(19) United States
(12) Patent Application Publication
(10) Pub. No.: US 2022/0207204 A1
(43) Pub. Date: Jun. 30, 2022

(54) METHOD AND DEVICE FOR VISUALIZING REPLACEMENT PARTS

(71) Applicant: Inventio AG, Hergiswil (CH)

(72) Inventors: Khanh Nguyen, Aarburg (CH); Stefano Carriero, Cham (CH)

(21) Appl. No.: 17/595,259

(22) PCT Filed: May 12, 2020
(86) PCT No.: PCT/EP2020/063208

§ 371 Date: Nov. 12, 2021

(30) Foreign Application Priority Data
May 20, 2019 (EP) 19175288.0

(51) Int. Cl. G06F 30/13; G06F 30/20; G06V 10/22; G06V 10/94; G06T 19/20; G06T 7/70; G06T 7/00

(52) U.S. Cl. CPC G06F 30/13; G06F 30/20; G06V 10/235; G06T 2219/2016; G06T 19/20; G06T 7/70; G06T 7/0006; G06V 10/95

(57) ABSTRACT

A method for visualizing replacement parts, e.g. for a passenger transport system, including the steps: displaying a list of possible replacement parts on a screen of a mobile device and prompting for selection of a specific replacement part; downloading 3D data of the selected replacement part from an external server via a network, the 3D data containing spatial information regarding visually discernable properties of the selected replacement part; displaying a perspective view of the selected replacement part with the visually discernable properties on the screen from an initial viewing angle; determining a change in an orientation of the mobile device in an altered orientation; and displaying a perspective view of the selected replacement part with the visually discernable properties from an altered viewing angle corresponding to the altered orientation thereby assisting a maintenance engineer to easily and intuitively inspect and reliably choose a replacement part for a defective component.

### FIELD

The present invention relates to a method and a device for visualizing replacement parts. The invention also relates to a computer program product which is configured to carry out, implement or control the method according to the invention, as well as a computer-readable medium with such a computer program product stored thereon.

### BACKGROUND

Products such as complex machines can consist of a large number of individual components. For example, due to wear or damage it may be necessary to replace components. To this end, it is typically necessary to reliably discern an identity, a function and/or other characteristic properties of a component to be replaced in order to then be able to replace it with a replacement part that has the same effect.

Using the example of a repair of a passenger transport system such as an elevator, an escalator or a moving walkway, which tasks or problems can arise when replacing components is explained below. However, similar tasks or problems can also arise when replacing components of other complex products, for example in the context of a repair of a motor vehicle or the like.

In the event of a defect in a passenger transport system, a maintenance engineer generally has to come to the passenger transport system in order to check how the defect can be remedied. If the maintenance engineer comes to the conclusion that a component needs to be replaced, he is faced with the task of discerning the identity, function and/or other characteristic properties of the component in order to be able to order a suitable replacement part. This can be difficult in individual cases, because the maintenance engineer should be able to maintain a large number of differently constructed passenger transport systems, possibly from different manufacturers, and various components can be installed in these passenger transport systems.

The maintenance engineer can ordinarily have access to component lists or catalogs, which are made available, for example, by manufacturers of the components or replacement parts and in which the components are characterized. In such component lists, identification numbers, functions and/or dimensions of a component or an associated replacement part are often specified. In some cases, images or photos of components or replacement parts are also shown in the component lists or catalogs.

However, practice shows that in some cases it can be difficult for a maintenance engineer to correctly identify the component to be replaced in order to be able to order a suitable replacement part. In particular, components with different functions or different other properties can look very similar to one another. Despite the visual similarity, for example, connections, dimensions, add-on parts or the like can differ in detail.

It can therefore happen that the maintenance engineer inadvertently selects and orders the wrong replacement part from the component list and only when attempting to install this component as a replacement part in the defective elevator system does he recognize that the defective component was discerned incorrectly and that the replacement part therefore cannot be installed. As a result, the repair of the defective passenger transport system can in particular be delayed and/or the effort for maintenance or repair can be significantly increased.

### SUMMARY

Among other things, there may be a need for a method and a device with the aid of which it can be made easier for a maintenance engineer to reliably identify a component to be replaced or to identify a suitable replacement part. Furthermore, there may be a need for a computer program product which can be used to carry out, implement or control such a method, as well as for a computer-readable medium with such a computer program product stored thereon.

Such a need can be met by the subject matter according to any of the advantageous embodiments that are defined in the following description.

According to a first aspect of the invention, a method for visualizing replacement parts, in particular for visualizing replacement parts for a passenger transport system, is proposed. The method comprises at least the following steps, preferably in the order provided:
displaying a list of possible replacement parts on a screen of a processor-controlled mobile device and prompting for selection of a specific replacement part from the displayed list;
downloading 3D data of the specifically selected replacement part from an external server via a network, the 3D data containing spatial information regarding visually discernable properties of the selected replacement part;
displaying a perspective view of the specifically selected replacement part with its visually discernable properties on the screen of the processor-controlled mobile device from an initial viewing angle;
determining a change in an orientation of the processor-controlled mobile device in an altered orientation; and
displaying a perspective view of the specifically selected replacement part with its visually discernable properties on the screen of the processor-controlled mobile device from an altered viewing angle corresponding to the altered orientation.

According to a second aspect of the invention, a mobile device with a processor and a screen is proposed, the mobile device being configured to execute, control or implement the method according to an embodiment of the first aspect of the invention.

According to a third aspect of the invention, a computer program product is proposed which has computer-readable instructions which, when executed on a processor-controlled mobile device, cause the mobile device to execute, control or implement the method according to an embodiment of the first aspect of the invention.

According to a fourth aspect of the invention, a computer-readable medium is proposed, in which a computer program product according to an embodiment of the third aspect of the invention is stored.

Possible features and advantages of embodiments of the invention can be considered, inter alia and without limiting the invention, to be based upon the concepts and findings described below.

Briefly summarized, an idea on which the present invention is based can be seen in the use of options such as those offered by modern processor-controlled mobile devices such as intelligent cell phones (smartphones) or portable computers (laptops, netbooks, etc.), for example to allow a maintenance engineer in this situation to help identify a suitable replacement part for a component to be replaced. The mobile device is initially used to display a list of possible replacement parts similar to a conventional component list or a catalog on the mobile device's screen. The maintenance engineer can then select a specific replacement part from this list, from which he assumes, for example, that a defective component can be replaced. For this specific replacement part, additional information can then be downloaded from an external server serving as an information source. This information includes, in particular, 3D data relating to visually discernable properties of the specific replacement part. Based on these 3D data, the specific replacement part can then be displayed in a perspective view in a way that is easy to interpret for the maintenance engineer. The perspective view is initially visualized from an initial viewing angle. In order to allow the maintenance engineer to be able to view selected specific replacement parts not just from one viewing angle, but to be able to vary this viewing angle, provision is also made to monitor the current orientation of the mobile device itself and to interpret a change in this orientation as an indication that the maintenance engineer would like to see the replacement part from a viewing angle corresponding to the altered orientation of the mobile device. Accordingly, in response to the change in the orientation of the mobile device, the replacement part can be shown in a perspective view from an altered viewing angle which corresponds to the altered orientation. The maintenance engineer can thus easily and intuitively inspect the selected replacement part from different viewing angles on the screen of the mobile device and, if necessary, compare its visually discernable properties to the component actually to be replaced. Only when he is sure, for example, that the selected replacement part is sufficiently identical in all visually discernable properties to the component to be replaced, can he order the replacement part. The risk of ordering the wrong component and thus the cost of repairing a machine to be serviced can thus be minimized.

Possible configurations and details of the individual method steps of the method presented are explained below.

The method described can be implemented in a processor-controlled mobile device, for example, with the aid of a computer program product or an application (“app”). The maintenance engineer's smartphone, for example, can serve as the mobile device. After a program start, for example, various preliminary queries can be carried out, on the basis of which it can be recognized which or which type of passenger transport system the maintenance engineer is currently working on. From this it can be concluded, among other things, which replacement parts could possibly be required in a specific maintenance case.

A list of possible replacement parts can then be created. This list of possible replacement parts can, for example, be a subset of a very large number of different replacement parts. The list can contain different kinds of information for each possible replacement part. The information can be provided in writing and/or in the form of images or pictograms. For example, the list can contain an associated name or an associated identification (ID) in the form of a sequence of characters and/or numbers for each possible replacement part. Furthermore, the properties of the replacement part can be described in writing. The replacement part is preferably also displayed visually, for example in the form of a photo, a drawing, a pictogram, a circuit diagram or the like. The data for the list of possible replacement parts can typically comprise a relatively small volume of data. Accordingly, these data can optionally have been stored in advance in the mobile device. Alternatively, this data can be downloaded from an external data source such as a data storage device to be carried along (for example a CD, a flash memory or the like) or a remote data storage device such as a server or a data cloud, adapted to the situation.

The list of possible replacement parts is then displayed on the screen of the mobile device, for example in the form of a list of brief written descriptions and/or visual representations for each of the replacement parts. The maintenance engineer can display the list as a whole or in parts or, if necessary, also search the list for specific search terms, features, or the like. The technician is then explicitly or implicitly prompted for selection of a specific replacement part from the displayed list shown, which part he assumes, for example, can replace a defective component.

After a specific replacement part has been selected in this way, 3D data for this specific replacement part are downloaded from an external server via a network. In this context, 3D data is understood to mean data which three-dimensionally indicate visually discernable properties of a replacement part, i.e. in three spatial directions. Visually discernable properties should be optical properties of the replacement part that can be perceived by a person with their eyes. The 3D data thus indicate, for example, a geometry of an outer surface, i.e. for example dimensions, curvatures, edges, etc. of the outer surface of the specific replacement part. Furthermore, the 3D data can indicate which color, colors or color gradients are present on the outer surface or parts thereof. Other visually discernable properties such as, for example, reflective properties (matte, glossy, metallic glossy) can also be specified in the 3D data.

It is possible to have created the 3D data for a replacement part in advance. For example, when designing or developing components, it is common practice to specify geometric properties and/or surface properties in the form of CAD data (Computer Aided Design). 3D data of a replacement part in the form of CAD data can therefore already be available from a manufacturer of the replacement part, for example, and kept ready for download in a database. In this case, CAD data can advantageously indicate the visually discernable properties of an object in a way that makes it possible to display the object in a perspective view from different viewing angles without excessive effort in terms of data storage and/or computing capacity. For example, geometric properties of the object can be specified in a vector-oriented manner.

Alternatively, 3D data of a replacement part can also be determined in another way, for example with the aid of a three-dimensional optical scanning (3D scan), three-dimensional photography or the like.

The 3D data can have a considerable data volume. In particular, the data volume of 3D data for a replacement part can be significantly larger than a data volume of the data relating to this replacement part in the previously described list of possible replacement parts. In addition, replacement parts can experience changes over time with regard to their visual properties, for example due to technical developments, changes in design specifications, etc., so that the relevant 3D data should be kept continuously updated.

Accordingly, it can be disadvantageous to store the 3D data directly in the mobile device and then to read it from a memory from there if necessary. Instead, the 3D data should generally be stored in an external server. Such a server can be part of a data cloud. The server can be located a long way away from a system or machine that is currently to be maintained. The 3D data can then, for example, be provided and/or updated or maintained by a manufacturer or developer of replacement parts.

If necessary, the 3D data can then be downloaded from the external server. This can be done over a network such as the Internet. In particular, the download can take place via a wireless network such as a radio network. Processor-controlled mobile devices usually have wireless data interfaces (e.g. WLAN, 3G/4G mobile radio, etc.), via which the 3D data can be downloaded without any problems.

After the 3D data are available in the processor-controlled mobile device, the specifically selected replacement part with its visually discernable properties can be shown in a perspective view on the screen of this mobile device. A perspective view can be understood to mean a view in which the replacement part is visualized on a merely 2-dimensional screen, but the spatial, i.e. 3-dimensional, properties of the replacement part are reproduced in perspective in a manner as would be the case with a view at the actually 3-dimensional replacement part. In other words, the perspective view represents an image, i.e. similar to a photo, of the 3-dimensional replacement part from a specified viewing angle.

However, the maintenance engineer should not only be given the option of being shown the specifically selected replacement part only from the, for example, randomly predetermined initial viewing angle. Instead, it can be helpful for the maintenance engineer to have the replacement part displayed from different viewing angles, for example, in order to be able to compare it to the actual component to be replaced.

In order to facilitate this in a way that is intuitive and easy to carry out for the maintenance engineer, it is proposed that the current orientation of the processor-controlled mobile device or changes in this current orientation be determined continuously or at short time intervals. For example, the maintenance engineer can initially hold the mobile device in a certain orientation and the replacement part can be displayed in the initial viewing angle on the screen of the mobile device. If the maintenance engineer then swivels, rotates or otherwise changes its orientation, this can be recognized by the mobile device itself and can be understood as an indication that the maintenance engineer wishes to have the replacement part shown from a different viewing angle.

For example, acceleration sensors are often integrated in modern mobile devices which generate signals indicating the direction in which the mobile device is currently being accelerated. Such acceleration sensors can preferably determine accelerations in all spatial directions. A change in the orientation of the mobile device can then be inferred by suitable analysis of the signals from such acceleration sensors. Furthermore, displacements of the mobile device can also be detected.

Based on the knowledge of the determined change in orientation of the mobile device, the selected replacement part with its visually discernable properties can then be shown in a perspective view on the screen of the mobile device from a different viewing angle. The altered viewing angle can be selected to correspond to the altered orientation of the mobile device. In other words, the altered viewing angle can behave in relation to the initial viewing angle in the same or a similar way as the altered orientation of the mobile device in relation to the initial orientation of the mobile device. Changes in the angle of the orientation of the mobile device can correspond to angular changes in the viewing angle or at least scale with them in an unambiguous manner.

The maintenance engineer can thus obtain different viewing angles of the replacement part shown in a perspective view on the screen by specifically reorienting his mobile device.

It can possibly be provided that the mobile device can first be brought into a specific initial orientation before changes in the orientation of the mobile device on the basis of this initial orientation are determined. The initial orientation can be selected, for example, so that the maintenance engineer can see the real component from a viewing angle that corresponds to the initial viewing angle of the replacement part shown in virtual perspective on the screen. If, for example, the maintenance engineer defines this orientation of the mobile device as the initial orientation, he can then, for example, view the real component from different viewing angles and carry along and reorient his mobile device accordingly in order to visualize the selected replacement part on its screen in a corresponding perspective view in a corresponding viewing angle to get. The maintenance engineer can thus very easily compare the real component to the selected replacement part from different viewing angles.

In order to give the maintenance engineer a further option to be able to change the virtual viewing angle of the replacement part displayed on the screen, touches on the screen of the processor-controlled mobile device can also be determined and a size and/or orientation of the perspective view of the selected replacement part can be changed depending on the determined touches.

For example, the screen of the mobile device can be touch-sensitive, i.e. configured as a touchscreen. With the aid of such a screen, touches on the screen that a technician makes with his fingers, for example, can be recognized. In particular, motions of fingers on the screen can be recognized. These motions can then be analyzed and recognized as an indication that the maintenance engineer would like a perspective view of the selected replacement part from a different viewing angle and/or in a different size.

For example, the maintenance engineer can touch a reference point on the screen with his finger and then move it to change the desired viewing angle. Furthermore, the maintenance engineer can, for example, mark a region with two fingers and indicate by moving the two fingers relative to one another that an enlarged or reduced view of the replacement part is desired. In this way, the maintenance engineer can, for example, change the initial viewing angle at which the replacement part is initially shown in a perspective view on the screen and adjust the size of the perspective view in such a way that it corresponds to the maintenance engineer's view of the real component to be replaced, thereby simplifying a visual comparison of the real component and the virtually represented replacement part.

According to one embodiment, the method presented here for visualizing a replacement part can be advantageously supplemented by additionally taking a photo with a camera of the processor-controlled mobile device and displaying the photo together with the perspective view of the specifically selected replacement part on the screen of the processor-controlled mobile device.

Processor-controlled mobile devices usually have a built-in camera that can be used to take photos. The camera is often arranged on a side of the mobile device opposite to the screen.

For the application described here, the mobile device with its camera can thus be directed towards a component to be replaced, and then a photo can be taken of the component and, if appropriate, of the surroundings of the component. This photo can then be displayed on the screen of the mobile device together with the perspective view of the replacement part specifically selected beforehand. As a result, the maintenance engineer can simultaneously see the photo of the real component and the perspective view of the selected replacement part on the screen, and can thus easily compare them to one another.

In particular, in a special embodiment, the photo and the perspective view of the specifically selected replacement part can be shown superimposed at least in certain regions.

In other words, the photo and the perspective view do not need to be shown separately, for example side by side. Instead, it can be advantageous to have the perspective view of the replacement part overlap with the photo or to integrate it into the photo. If necessary, the maintenance engineer can be given the option of specifying the position at which the perspective view of the replacement part is to be displayed in the photo, for example by dragging the perspective view to a desired position by touching the screen. This makes it particularly easy to compare the replacement part and the image of the real component.

It may even be provided that the perspective view of the replacement part and/or the photo is shown as partially transparent and the view of the replacement part and the reproduction of the real component are directly superimposed. In this way, for example, contours of the replacement part and the real component can be compared particularly well to one another.

In a further special embodiment, the method can be supplemented by transmitting the photo together with the perspective view in the altered viewing angle corresponding to the altered orientation to an external server.

In other words, the maintenance installer can be given the opportunity not only to take a photo and compare its content to the perspective view of the selected replacement part, but, after he has changed the orientation of the mobile device in a desired way so that it makes sense to him to select the viewing angle for the perspective view of the replacement part, to be able to transmit the photo together with the perspective view to an external server.

In the event that the maintenance engineer is not entirely sure whether the selected replacement part is actually suitable for replacing a defective component, for example, he can transmit a photo of the defective component directly together with the replacement part he has already selected in a suitable perspective view to the external server. There, the transmitted image data can be checked, for example, by specialists from a manufacturer of the replacement part, and the maintenance engineer can then receive feedback on whether the replacement part can actually replace the defective component. Handling the mobile device for recording and transmitting the corresponding data is particularly intuitive for the maintenance engineer.

The mobile device according to the second aspect of the present invention is a small, portable device which has suitable processor power and a suitable screen in order to be able to display 3D data of a replacement part in a perspective view. Furthermore, the mobile device preferably has a data memory in which the 3D data and possibly also data relating to the list of possible replacement parts can be stored. In addition, the mobile device preferably has an interface, preferably a wireless interface, via which the 3D data can be downloaded from an external server. Finally, the mobile device also preferably has an acceleration sensor system, with the aid of which a current orientation of the mobile device can be determined.

The mobile device can be programmable in such a way as to make it possible, with the aid of a special computer program product according to an embodiment of the third aspect of the invention or an app, to execute, control or implement embodiments of the method described herein. The computer program product can be programmed in any computer language that the mobile device can understand.

The computer program product can be stored on a computer-readable medium according to an embodiment of the fourth aspect of the invention, such as a data storage medium. Such a computer readable medium can be portable. For example, the computer-readable medium can be a CD, a DVD, a flash memory or the like. Alternatively, the computer program product can be stored on a stationary computer or server, from which it can be downloaded. The server can be part of a data cloud. The computer program product can be downloaded over a network such as the Internet.

It must be noted that some of the possible features and advantages of the invention are described herein with reference to different embodiments of the method for visualizing replacement parts, on the one hand, and a mobile device usable for this purpose, on the other hand. A person skilled in the art recognizes that the features can be combined, adapted or replaced as appropriate in order to arrive at further embodiments of the invention.

Embodiments of the invention will be described in the following with reference to the accompanying drawings, wherein neither the drawings nor the description are intended to be interpreted as limiting to the invention.

### DESCRIPTION OF THE DRAWINGS

FIGS. 1A to 1D illustrate steps of a method according to the invention for visualizing replacement parts.

The drawings are merely schematic and not true to scale. Like reference signs denote like or equivalent features in the various drawings.

### DETAILED DESCRIPTION

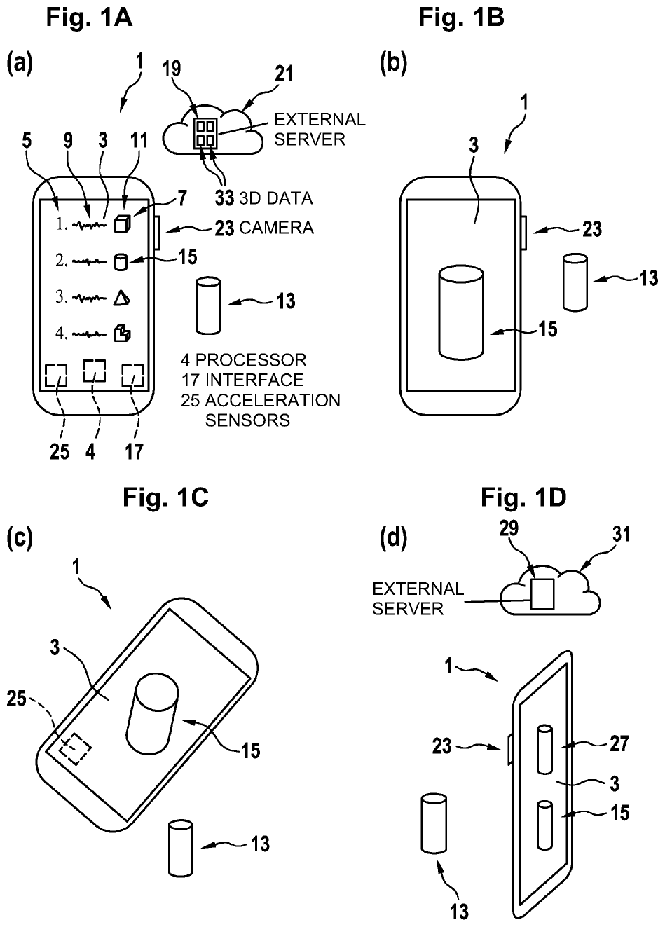

FIGS. 1A to 1D illustrate various steps (a) to (d) of an embodiment of a method according to the invention for visualizing replacement parts.

In a first step (a), as illustrated in FIG. 1A, a list 5 of possible replacement parts 7 is displayed on the screen 3 of a mobile device 1 controlled by a processor 4. In the list 5, written information 9 and/or pictorial information 11 can be shown for each possible replacement part 7.

A maintenance engineer who has been entrusted with the maintenance of a passenger transport system, for example, and would like to replace a defective component 13 therein, can select a specific replacement part 15 from this list 5.

The mobile device 1 can then contact an external server 19, for example via an interface 17, in which 3D data 33 on a large number of replacement parts 7 are stored. The server 19 can be operated by a manufacturer of replacement parts 7, for example. The 3D data 33 can, for example, be CAD data that the manufacturer created in the course of developing and/or manufacturing the replacement parts 7. The server 19 can be part of a data cloud 21. The mobile device 1 can then download 3D data 33 on the specifically selected replacement part 15 from the server 19, preferably by wireless data transmission.

As illustrated in step (b) shown in FIG. 1B, the mobile device 1 can then show visually discernable properties of the selected replacement part 15, as defined in the downloaded 3D data 33, on the screen 3 in a perspective view. The perspective view is initially based on an initial viewing angle.

The maintenance engineer can then, as illustrated in step (c) shown in FIG. 1C, view the replacement part 15 shown on the screen 3 of the mobile device 1 from different viewing angles. For this purpose, the maintenance engineer can move the mobile device 1, in particular swivel, rotate and/or turn it, in order to change its orientation. The orientation of the mobile device 1 in an altered orientation can be determined with the aid of acceleration sensors 25 (FIG. 1A) of the mobile device 1. The specifically selected replacement part 15 can then be shown in a perspective view in an altered viewing angle corresponding to the altered orientation.

Optionally, in an additional step (d), as illustrated in FIG. 1D, a camera 23 of the mobile device 1 can be used to take a photo 27 of the component 13 to be replaced. The photo 27 can then be displayed on the screen 3 together with the perspective view of the replacement part 15 specifically selected beforehand. The photo 27 and the perspective view of the replacement part 15 can be visualized next to one another or in an at least partially overlapping manner (not shown for reasons of clarity).

If necessary, the photo 27 together with the perspective view of the replacement part 15 can be transmitted from the mobile device 1 to an external server 29, which in turn can be part of a data cloud 31, in order to have it analyzed there to determine whether the replacement part 15 can really suitably replace the component 13.

In summary and with revised wording, an idea on which the approach presented here is based can be seen as displaying a type of virtual hologram for each replacement part in order to make a selection easier for a field technician. Source data for the hologram can come from CAD data as it was previously created for replacement parts. The hologram or the perspective view of the replacement part can be generated on the screen of the mobile device using the integrated camera, acceleration sensors and graphics software modules. An existing replacement parts catalog or an app configured for this purpose can be expanded in order to gain access to the 3D models of each replacement part. The app will then calculate the design and show it on the screen of the mobile device, for example as an overlay image over a camera image. When the 3D model is shown, the user can pivot his mobile device. Based on the acceleration sensor values, the app will rotate the 3D model in the corresponding axis. Because the background on the screen shows the current camera image, the user will get a feeling of a holographic replacement part when the mobile device is moved in one axis. Overall, a required replacement part can be better identified as a result, because the user can receive a 3D image of the replacement part and a 360° view of the part. As a result, fewer incorrect orders can be made for replacement parts, thereby saving costs and/or shortening downtimes for defective passenger transport systems.

Finally, it should be noted that terms such as “comprising,” “having,” etc. do not preclude other elements or steps, and terms such as “a” or “an” do not preclude a plurality. Furthermore, it should be noted that features or steps which have been described with reference to one of the above embodiments may also be used in combination with other features or steps of other embodiments described above.

In accordance with the provisions of the patent statutes, the present invention has been described in what is considered to represent its preferred embodiment. However, it should be noted that the invention can be practiced otherwise than as specifically illustrated and described without departing from its spirit or scope.

1-11. (canceled)

12. A method for visualizing replacement parts for a system, the method comprising the steps of:
displaying a list of possible replacement parts on a screen of a processor-controlled mobile device and enabling selection of a specific replacement part from the displayed list by a user of the mobile device;
downloading 3D data of a selected replacement part from an external server via a network in response to a selection by the user, the 3D data containing spatial information regarding visually discernable properties of the selected replacement part;
displaying a perspective view of the selected replacement part with the visually discernable properties on the screen of the mobile device from an initial viewing angle;
determining a change in an orientation of the mobile device when the mobile device is moved to an altered orientation; and
displaying another perspective view of the selected replacement part with the visually discernable properties on the screen of the mobile device from an altered viewing angle corresponding to the altered orientation.

13. The method according to claim 12 wherein the system is a passenger transport system.

14. The method according to claim 12 wherein the altered orientation of the mobile device is determined on a basis of signals provided by acceleration sensors in the mobile device.

15. The method according to claim 12 including determining touches on the screen of the mobile device and changing at least one of a size and an orientation of either of the perspective views of the selected replacement part depending on the touches determined.

16. The method according to claim 12 including taking a photo of a component of the system with a camera of the mobile device and displaying the photo together with either of the perspective views of the selected replacement part on the screen of the mobile device.

17. The method according to claim 16 wherein the photo and the either perspective view of the selected replacement part are displayed at least partially superimposed.

18. The method according to claim 16 including transmitting the photo together with the another perspective view of the selected replacement part in the altered viewing angle to an external server.

19. The method according to claim 12 wherein the 3D data are CAD data of the selected replacement part.

20. The method according to claim 12 including downloading the 3D data from the external server via a wireless network.

21. A mobile device comprising:
a processor adapted to perform the method steps according to claim 12 for the system;
a camera for taking photos of components of the system; and
the screen for displaying the list and the perspective views.

22. The mobile device according to claim 21 including at least one acceleration sensor for signaling to the processor the altered orientation of the mobile device.

23. A computer program product comprising computer-readable instructions which, when executed by a processor-controlled mobile device, cause the mobile device to execute, control or implement the method steps according to claim 12.

24. A non-transitory computer-readable medium having the computer program product according to claim 23 stored thereon.
